(19) United States
(12) Patent Application Publication
(10) Pub. No.: US 2018/0112331 A1
(43) Pub. Date: Apr. 26, 2018

(54) ENABLING ARTIFICIAL THIN FILM MATERIAL STRUCTURES OF NON-LINEAR COMPLEX OXIDE THIN FILMS

(71) Applicant: U.S. Army Research Laboratory ATTN: RDRL-LOC-I, Adelphi, MD (US)

(72) Inventors: Melanie Will Cole, Albuquerque, NM (US); Mathew P. Ivill, Havre de Grace, MD (US); Daniel Shreiber, Pikesville, MD (US)

(21) Appl. No.: 15/788,972

(22) Filed: Oct. 20, 2017

Related U.S. Application Data
(60) Provisional application No. 62/411,022, filed on Oct. 21, 2016.

(51) Int. Cl. C30B 30/02; B05D 1/00; B05D 3/06; C30B 29/32; C01G 23/00

(52) U.S. Cl. CPC C30B 30/02; B05D 1/005; C01G 23/006; C30B 29/32; B05D 3/06

(57) ABSTRACT

Integrated non-linear complex oxide (NLCO) thin film artificial structures include tailored microstructural and crystalline phases for designed material architectures and a method of fabrication. A nano-scale poly crystal-amorphous composite film includes an amorphous matrix surrounding crystalline domains/inclusions of the form of particles, platelets, rods and/or needles, etc. Artificial thin film layered material configurations include bilayers, repeat “unit cell” bilayers with variable stacking periodicity (N), and multilayers whereby each individual layer, ni, exhibits a different microstructural crystallinity phase state, hence the microstructural phase state is variable in the vertical direction perpendicular to the substrate. NLCO elements can be organized in array configurations. The method to create the integrated NLCO thin film artificial structures combines metal-organic solution deposition (MOSD) film fabrication and microwave irradiation (MWI) processing, is tailorable and creates artificial thin film material structures composed of differing microstructural crystalline phase states simultaneously within a single thermal treatment step.

### CROSS REFERENCE TO RELATED APPLICATION

This application claims the benefit of U.S. Provisional Patent Application No. 62/411,022 filed on Oct. 21, 2016, the contents of which, in its entirety, is herein incorporated by reference.

### GOVERNMENT INTEREST

The embodiments herein may be manufactured, used, and/or licensed by or for the United States Government without the payment of royalties thereon.

### BACKGROUND

### Technical Field

The embodiments herein generally relate to tunable non-linear complex oxide (NLCO) thin films, and more particularly to methods for enhancing the material properties of NLCO thin films to provide enhanced material properties for tunable RF/MW devices.

### Description of the Related Art

Many generic process science methods have been developed and implemented to enhance the dielectric response of NLCO thin films. Such methods typically include the creation of composite/multiphase films. These process science techniques generally combine materials, dopants, compositions and growth attributes which provide a material property gain or leveraged benefit of the various components involved. Unfortunately, traditional process science methods have generally only achieved agility of the chemical composition (i.e., compositional phase state) and/or dimensions (i.e., thickness, shape and/or size) of the variants which compose the artificial material thin film structures. To date there has been no known demonstration of artificial thin film material structures with variable microstructural crystallinity; i.e., thin film structures comprising variants ranging from amorphous to fully crystalline phase states. The reason for this is because typically all NLCO thin film material designs, inclusive of the artificial thin film material structures, must be thermally treated (annealed) to achieve the desired dielectric response required for device-quality materials. Accordingly, there is generally no conventional process science method that achieves microstructural agility; i.e., variable microstructure (variable film crystallinity) within a single thermal treatment process science step.

There are several conventional material thermal/heat treatment strategies used in the industry. Some material thermal treatment methods include conventional furnace annealing (CFA), rapid thermal processing (RTP), microwave sintering (MWS), and microwave irradiation (MWI) processing. Complex oxide thin film materials such as BaTiO₃ (BT), SrTiO₃ (ST), BaₓSr₁₋ₓTiO₃ (BST) and similar dielectric materials generally require a heat/thermal treatment or annealing step to crystallize the film and achieve device quality dielectric and insulation material properties. The majority of the conventional thin film heating/crystallization techniques are based on heating methods which possess high thermal budgets and do not lend agility to create artificial thin film material structures comprising tailored microstructural crystallinity phase state material design architectures, and do not permit the creation of simultaneous variable microstructural crystallinity phase states in a single thermal process step and they do not permit the precise control of such microstructurally tailored artificial thin film material design architectures.

### SUMMARY

In view of the foregoing, an embodiment herein provides an integrated non-linear complex oxide (NLCO) thin film artificial structure comprising tailored microstructural crystallinity phase states material design architectures and a method of fabrication thereof. One embodiment herein provides a nano-scale poly crystal-amorphous composite film comprising a matrix surrounding domains/inclusions in the form of particles, platelets, rods and/or needles, and the like, whereby the matrix and inclusions are of a different microstructural crystalline phase state with respect to that of the matrix. The matrix may be amorphous and the inclusions may be crystalline.

A process provided by the embodiments herein also permit the creation of novel NLCO elements organized in array configurations. The fabricated artificial thin film material structures enable tailorable and enhanced dielectric and insulation material properties to enable enhanced signal intensity/transmission, low power consumption/battery draw and agility in tunable radio frequency/microwave frequency (RF/MW) devices. The method to create the integrated NLCO thin film artificial structures according to the embodiments herein, which combines metal-organic solution deposition (MOSD) film fabrication and microwave irradiation (MWI) processing, inclusive, is tailorable and creates artificial thin film material structures comprising differing microstructural crystalline phase states simultaneously within a single thermal treatment step.

The embodiments herein further provide a thin film processing technique which combines chemical solution thin film material synthesis, wherein the MOSD technique, in combination with a process parameter-optimized MWI thermal processing method, is used to achieve artificial thin film structures with variable microstructural crystallinity phase states, wherein the structures are nano-scale poly crystal-amorphous-composites, bilayers, repeat “unit cell” bilayers with variable stacking periodicity (N) and multilayers whereby each individual layer, nᵢ, exhibits a different microstructural crystallinity phase state, hence the microstructural phase state is variable in the vertical direction perpendicular to the substrate support.

The embodiments herein provide desirable attributes such as low thermal budget to allow integration with non-refractory substrates/materials to ensure device affordability, reduced effects of thermal strain to ensure optimal dielectric response, reduced processing time to ensure efficient manufacturability and to achieve tailored microstructural crystallinity phase state artificial material structures to enable enhanced dielectric and insulation response to allow enhanced signal intensity/transmission in frequency agile tunable devices. The process provided by the embodiments herein is semiconductor foundry friendly and allows scalable and cost effective manufacturability.

In accordance with the embodiments herein, the MOSD as-deposited film structures are thermally treated by exposure to MWI with optimized process parameters of frequency, power level, process time, pressure, ambiance and temperature. Moreover, the fabrication of the nano-scale poly-crystal-amorphous-composite film structures utilizes localized susceptor phases (LSPs) to produce the poly-crystal inclusions embedded in an amorphous matrix. The poly crystal-amorphous-composite film can be of the form whereby crystalline particles, platelets, rods and/or needles, or the like, are regularly dispersed within an amorphous matrix. The LSPs may also be deposited in a specific pattern to induce the poly-crystal domains in select areas. Such a selective crystallization can be used to fabricate a variety of artificial structures such as an array of crystalline NLCO material elements whereby the NLCO material elements are isolated from one another by an amorphous phase.

In accordance with another embodiment herein, the artificial material structure is in the form of a bilayer, a n-times repeat bilayer, or distinct individual layers within multilayer thin film structures, whereby the microstructural crystallinity phase state of each layer is variable ranging from fully crystalline to quasi-crystalline to amorphous and variations thereof. Here, the fabrication process does not necessarily utilize LSPs. Instead, each layer is synthesized whereby the individual layers are compositionally tuned/designed to be MW absorbing to create a fully crystalline layer or non-MW absorbing (opaque or transparent to MW) to create an amorphous microstructural phase state. Additionally, the layer composition may be compositionally tailored to create a wide range of varied microstructural phase states, bound by these two endmember phase states, ranging from amorphous to quasi-crystalline to fully crystalline. LSPs may be utilized in select situations to achieve desirable features to include, but are not limited to, near-single crystal microstructures. In all cases, the layered microstructural phase state is variable in the Z-direction; perpendicular to the substrate support. Generally, all of the artificial thin film structure material configurations provided by the embodiments herein can be created in either the metal-insulator-metal (MIM) or the coplanar device configurations.

The embodiments herein provide novel artificial thin film structures for RF/MW tunable device applications and a method of fabrication thereof. The method to create the integrated NLCO thin film artificial structures according to the embodiments herein, combines MOSD film fabrication and MWI processing, is tailorable, and creates artificial thin film material structures comprising differing microstructural crystalline phase states simultaneously within a single thermal treatment step.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 is a schematic diagram illustrating a nano-scale poly crystal-amorphous composite film according to an embodiment herein;

FIG. 2A illustrates is a process flow diagram illustrating a method for creating the poly-crystal domains in an amorphous matrix according to an embodiment herein;

FIG. 2B illustrates an example process whereby crystalline BaTiO₃ (BT) in an amorphous matrix of the same chemical composition is created according to an embodiment herein;

FIG. 3A is a schematic diagram of the metal-organic precursor solution according to an embodiment herein;

FIG. 3B is a schematic diagram of the BT amorphous/LSP particles within the precursor solution containing LSP according to an embodiment herein;

FIG. 3C is a schematic diagram of the MOSD derived amorphous film containing LSPs overlying a substrate support according to an embodiment herein;

FIG. 3D is a schematic diagram showing the MWI heating process according to an embodiment herein;

FIG. 4A is a reproduction of a Transmission Electron Microscopy (TEM) image of the as-prepared precursor showing a BaTiO₃ particle in the amorphous phase state according to an embodiment herein;

FIG. 4B is a reproduction of a TEM image of the microwave irradiated precursors showing a BaTiO₃ particle in the crystalline phase state according to an embodiment herein;

FIG. 5A is a schematic cross-sectional diagram representing a metal-insulator-metal (MIM) capacitor array fabricated in accordance with the embodiments herein;

FIG. 5B is a schematic plan view diagram representing the metal-insulator-metal (MIM) capacitor array of FIG. 5A fabricated in accordance with the embodiments herein;

FIG. 5C is a schematic cross-sectional and plan view diagram representing the metal-insulator-metal (MIM) capacitor array fabricated in FIGS. 5A and 5B whereby the amorphous phase is removed by selective dissolution in developer solvent according to an embodiment herein;

FIG. 6A is a schematic cross-sectional diagram illustrating the basic building block/unit cell of the integrated layered NLCO thin film artificial structures in the MIM device configuration according to an embodiment herein;

FIG. 6B is a schematic cross-sectional diagram illustrating a coplanar device configuration inclusive of the NLCO integrated bilayer artificial structure according to an embodiment herein;

FIG. 7A is a schematic cross-sectional diagram illustrating the MIM device configuration according to an embodiment herein;

FIG. 7B is a schematic cross-sectional diagram illustrating a coplanar device configuration inclusive of the integrated NLCO repeat bilayers with a variable stacking periodicity (N) artificial structure according to an embodiment herein;

FIG. 8 is a flow diagram illustrating a manufacturing process according to an embodiment herein;

FIG. 9A is a schematic cross-sectional diagram illustrating a multilayer artificial thin film material structure in a MIM device configuration according to an embodiment herein;

FIG. 9B is a schematic cross-sectional diagram illustrating a multilayer artificial thin film material structure in a coplanar device configuration according to an embodiment herein;

FIG. 10A illustrates a plan-view and 3D atomic force microscopy (AFM) images of a representative MOSD as-deposited amorphous BST60/40 film according to an embodiment herein;

FIG. 10B illustrates a plan-view and 3D AFM images of a representative MOSD as-deposited amorphous BST60/40 film after exposure to a process parameter-optimized MWI processing according to an embodiment herein;

FIG. 11A illustrates a cross-sectional high resolution scanning electron micrograph (SEM) image showing the crystalline nature of the BST60/40 film overlying a non-absorbing substrate after MWI processing according to an embodiment herein; and

FIG. 11B illustrates a cross-sectional high resolution SEM image showing the crystalline nature of the BST60/40 film with a bottom electrode (BE) that acts as a LSP, after MWI processing according to an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The embodiments herein provide a method for creating artificial thin film material structures offering enhanced material properties for tunable RF/MW devices. Technological systems applications for these devices include, but are not limited to, commercial wireless communications systems (cell phones), military hand held communications systems (soteware-defined radios), mobile electronic scanning antennas, phased array radars, and advanced electronic warfare (EW) systems.

The techniques provided by the embodiments herein for improving the material properties of NLCOs, also referred to as artificial thin film material structures, provide advances in manufacturing for tunable device applications. Specifically, such NLCO-based artificial thin film material structures realize significantly enhanced dielectric properties with respect to homogenous NLCO films at both low and GHz frequencies. Generally, artificial thin film material structures include bilayer, multilayer superlattices and/or nano-composites (nano-materials such as particles, platelets, or rods arranged in a highly-ordered fashion within a single homogenous film layer). Such artificial thin film material structures comprising NLCO thin film bilayers and superlattices (SLs) have been developed to obtain new functionality or enhanced properties over single homogeneous layer oxide thin films. Considerably different dielectric behavior of superlattices (bilayer and multilayers) and nano-composites with respect to their compositionally equivalent solid solutions are provided.

The dielectric loss of a NLCO film can be greatly improved by creating a composite film comprising of a low loss material (i.e., pyrochlores such as bismuth zinc niobate (BZN), incipient ferroelectrics such as ST, linear dielectrics such as Tantalum oxide (Ta₂O₅) etc.) with a traditionally higher loss, but highly tunable NLCO material such as BST. Similarly, acceptor doping serves to lower loss, while retaining the single phase-nature of the film. Combinational growth methods take advantage of the beneficial material properties associated with each growth technique. For example, RF sputtering offers highly textured columnar microstructure which serves to provide enhanced dielectric permittivity while the chemical solution film growth techniques (e.g., MOSD) provides the smooth surface morphologies to ensure better leakage characteristics. Therefore, creating a tri-layer thin film comprising a thick RF sputtered BST layer sandwiched between two thin MOSD deposited layers in contact with the top and bottom electrodes results in a high permittivity film with low leakage characteristics.

Generally, materials can be classified into three types based on their interaction with microwaves: (1) Opaque or electrical conductors where microwaves are reflected and do not penetrate. Such materials possess an extremely high dielectric loss factor. (2) Transparent or low dielectric loss (or conductivity) materials, in which microwaves are neither reflected nor absorbed, but are transmitted through the material with little attenuation. (3) Absorbers or high dielectric loss materials which absorb microwave energy to a certain degree based on the value of the dielectric loss factor and convert it to heat.

The dielectric properties of materials are important to assess the viability of the heating due to microwaves. Specifically, the ability of a dielectric material to absorb MW and store energy is given by the complex permittivity ε*, ε*=ε′−jε″, where the dielectric constant (ε′) signifies the ability of the material to store energy and the dielectric loss (ε″) represents the ability of the material to convert absorbed energy into thermal energy. The ratio of the dielectric loss to the dielectric constant is known as the loss tangent (tan δ), which is given as, tan δ=k″/k′=ε″/ε′, where k′ and k″ are the relative dielectric constant and relative dielectric loss, respectively, which are given as k′=ε′/ε₀ and k″=ε″/ε₀, where ε₀ is the permittivity of free space. Hence, materials with large values of loss tangent/dielectric loss couple with MW with great efficiency. Generally, ceramics with loss factors between the limits of 10⁻²<ε″<5 are good candidates for microwave heating. Ceramics with ε″<10⁻² are generally difficult to heat, while those with ε″>5 absorb most of the heating on the surface and not in the bulk. A greater heating effect within a sample is attributed by greater power absorption within the material. The amount of power absorbed by a material per unit volume is given by P=σ|E|²=2πfε₀εᵣ tan δ|E|², where E is the magnitude of the internal field, σ is the effective conductivity, f is the frequency, ε₀ is the permittivity of free space, εᵣ is the dielectric constant, and tan δ is the loss tangent.

Not all bulk materials are good MW absorbers at room temperature (i.e., these materials possess low loss at room temperature); however, many such ceramic materials possess dielectric loss factors that rapidly increase in magnitude with increasing temperature. Therefore, such materials absorb MW energy if they can be preheated to a suitable temperature using another heat source.

The embodiments herein provide an integrated NLCO thin film artificial structure comprising tailored microstructural crystallinity phase states material configurations and methods of fabrication. One embodiment herein comprises a nano-scale poly crystal-amorphous composite film comprising a matrix surrounding domains/inclusions in the form of particles, platelets, rods and/or needles, and the like, whereby the matrix and inclusions are of a different microstructural crystalline phase state with respect to that of the matrix. In one embodiment, the matrix is amorphous and the inclusions are crystalline. Another embodiment herein represents artificial thin film layered material configurations comprising bilayers, repeat “unit cell” bilayers with variable stacking periodicity (N) and multilayers whereby each individual layer, nᵢ, exhibits a different microstructural crystallinity phase state, hence the microstructural phase state is variable in the vertical direction perpendicular to the substrate support. The process provided by the embodiments herein also permits the creation of novel NLCO elements organized in array configurations. The fabricated artificial thin film material structures enable tailorable and enhanced dielectric and insulating material properties to enable enhanced signal intensity/transmission, low power consumption/battery draw and agility in tunable radio frequency/microwave frequency (RF/MW) devices. The method to create the integrated NLCO thin film artificial structures according to the embodiments herein, combines MOSD film fabrication and MWI processing, inclusive, is tailorable, and creates artificial thin film material structures comprising differing microstructural crystalline phase states simultaneously within a single thermal treatment step. The embodiments herein, inclusive of the associated process science methodology and materials, are foundry friendly, scalable and affordable.

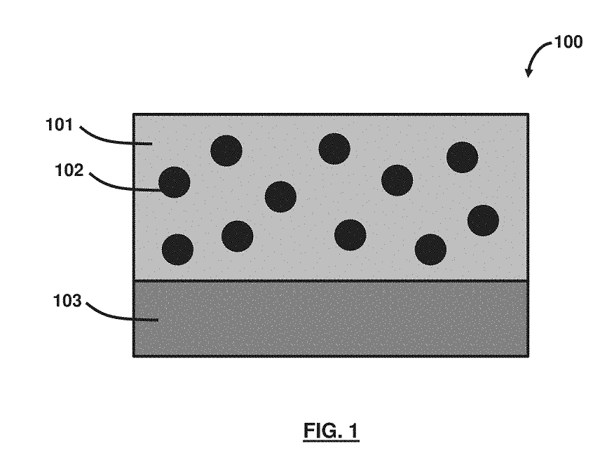

Referring now to the drawings, and more particularly to FIGS. 1 through 11B, where similar reference characters denote corresponding features consistently throughout the figures, there are shown preferred embodiments. One embodiment herein, generally, is the creation of nano-scale poly crystal-amorphous composite film artificial structures utilizing a LSP inside an amorphous matrix of a desired material. FIG. 1 is a schematic representation of an embodiment of a nano-scale poly crystal-amorphous composite film 100 comprising a matrix 101 surrounding inclusions in the form of particles 102 created by a process involving overlying a substrate support 103. More specifically, the tailored microstructurally crystalline phase state artificial structure 100 comprises poly-crystal domains (i.e., LSPs) 102 which are separated by an amorphous matrix 101 of similar composition. Generally, the LSPs 102 comprise a medium-to high-microwave absorbing material. The LSPs 102 could be crystalline or amorphous phases dispersed or layered into the matrix medium 101.

In one embodiment, the LSPs 102 are added or deposited as an additional phase, such as, but not limited to, the inclusion of energy absorbing carbide particles. In another embodiment, the LSPs 102 are developed in-situ from the solution, such as the precipitation of absorbing particles from a precursor solution. The LSPs 102 may be configured in various sizes; however, in one example embodiment herein a homogeneous distribution of LSPs 102 on the order of 10's of nanometers in diameter or thickness is utilized. Generally, the LSPs 102 may be configured of various geometries, such as particles, tubes and cylinders, platelets, cubes, films, etc. In one embodiment, the LSPs 102 are configured as particles.

The LSPs 102 behave as local-source susceptors to convert the impinging microwave energy into localized heating. Thus, the susceptor phases act as local-source radiators inside the material to be processed. The MWI process is capable of uniform, volumetric heating, thus all the susceptors will be heated, to first order, to similar temperature.

The penetration depth of the microwaves into the LSPs 102 is dependent upon the skin depth of the chosen material. However, there is no specification that the microwave energy must fully penetrate the LSP 102 since the microstructural development relies on localized heating that emanates from the surface of the LSP 102 into the amorphous matrix 101 during microwave sintering.

The amorphous matrix 101 of the nano-scale poly crystal-amorphous composite artificial thin film structure 100 is chosen to be a low loss microwave material, such as, but not limited to, aluminum oxide (Al₂O₃), strontium titanate (ST), or the like. The material 101 will not absorb the impinging microwave energy during the MWI processing and the temperature of the amorphous material 101 will not be raised significantly in comparison to the rapid heating of the susceptor phases. Heating of the amorphous matrix 101 can occur via conductive heating by contact to the susceptor phases.

In one embodiment, a thermal gradient is created which spreads uniformly starting from the susceptor phase into the surrounding amorphous matrix 101. The first portion of the amorphous matrix 101 to crystallize may be the boundaries in direct contact to the LSPs 102. An additional driving force for crystallization of the matrix 101 is the heterogeneous nucleation between the LSPs 102 and the matrix 101.

Crystallization relies on temperature and time; therefore, kinetics of the crystallization front can be controlled by the microwave power and the sintering time. Both of these parameters are easily controlled with modern MWI instrumentation. This results in beneficial control of the size of the poly-crystals and thus the width of the remaining amorphous boundary layer. The MWI process parameters may be tuned/controlled so that the growth of the crystalline particles does not proceed to a fully crystalline microstructure. Moreover, the crystalline particles may be separated by the remaining amorphous phase of the same composition.

The concentration of LSPs 102 directly controls the number of poly-crystals (in an almost one-to-one ratio for uniformly dispersed LSPs 102) and the sintering/MWI parameters determines the poly-crystals' size.

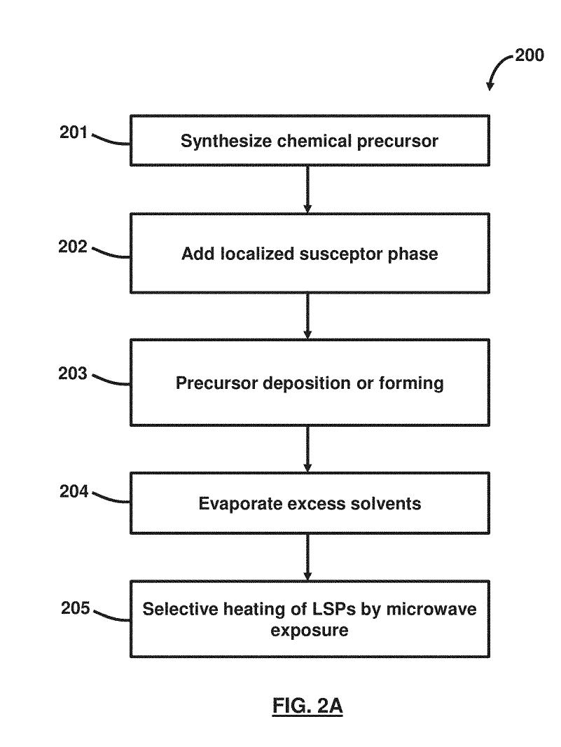

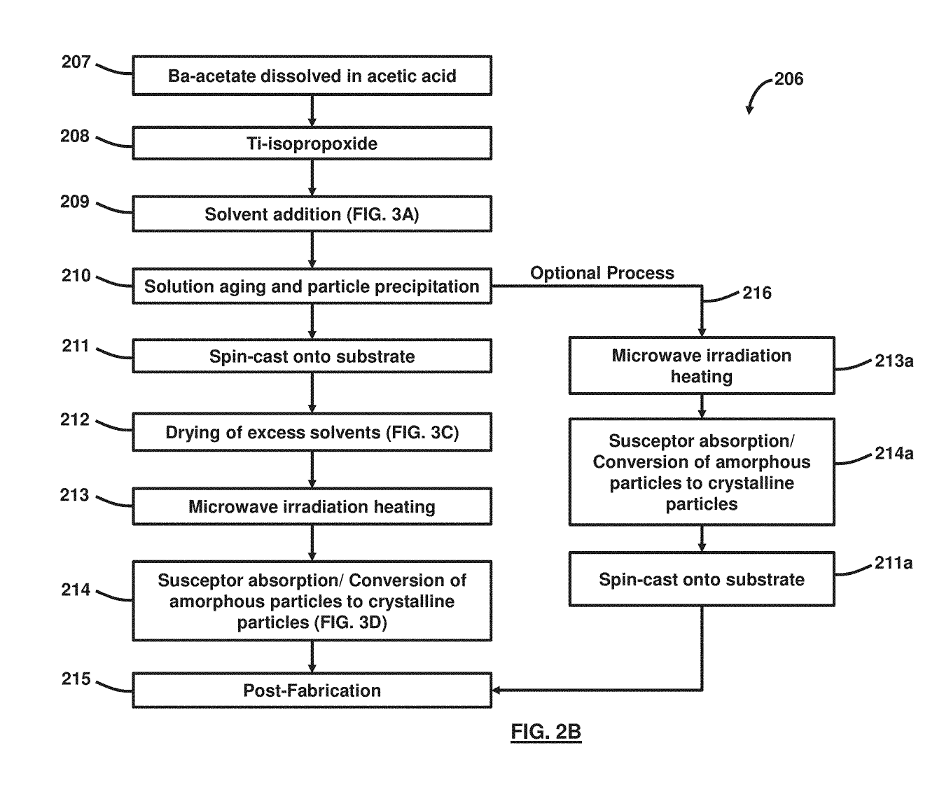

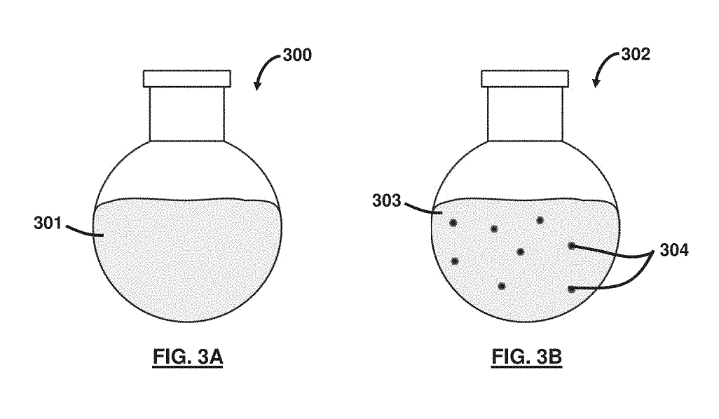

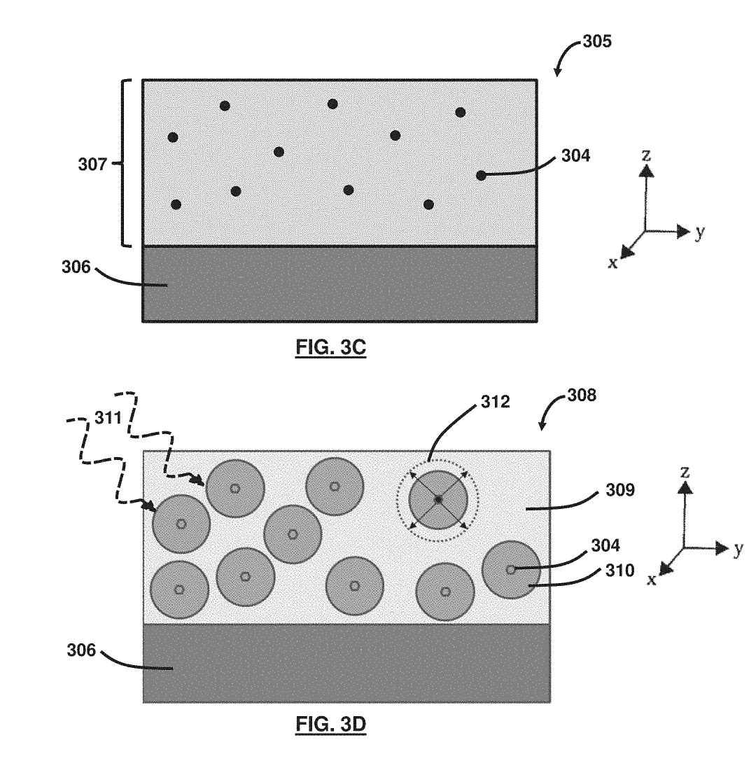

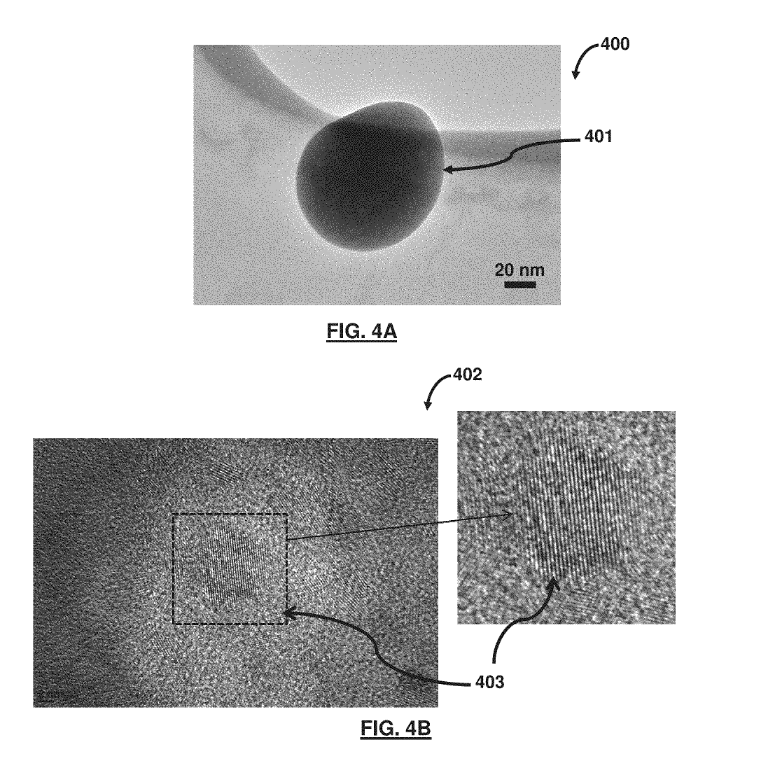

A flow diagram illustrating exemplary processes according to an embodiment herein is presented in FIGS. 2A and 2B, with reference to FIG. 1. Specifically, FIG. 2A presents the process 200 for creating the poly-crystal domains 102 in an amorphous matrix 101. FIG. 2B describes a specialized example process 206 whereby crystalline BaTiO₃ (BT) in an amorphous matrix of the same chemical composition is created. Accompanying illustrations of various steps in the process and referenced items are provided in FIGS. 3A through 3D, wherein FIG. 3A is a schematic diagram of the metal-organic precursor solution 301 according to an embodiment herein, FIG. 3B is a schematic diagram of the BT amorphous/LSP particles 304 within the precursor solution containing LSP 303 according to an embodiment herein, FIG. 3C is a schematic diagram of the MOSD derived amorphous film 307 containing LSPs 304 overlying a substrate support 306 according to an embodiment herein, and FIG. 3D is a schematic diagram showing the MWI heating process whereby MW irradiation 311 promotes the heating of the LSP 304 to create crystalline BT domains 310 which encapsulate the LSP 304 and are separated by the remaining amorphous BT matrix 309. The solidification front 312 from the LSP is also shown, according to an embodiment herein.

Again, with reference to FIG. 2A the method 200 for creating the poly-crystal domains 102 in an amorphous matrix 101 is described. Elements of the process comprise synthesis of chemical precursors in step (201), followed by the addition of LSPs via dispersion or precipitation in step (202), deposition or forming of the precursor solution on a substrate support in step (203) (i.e., spin-coating, casting, extrusion, etc.), evaporation of solvents and the formation of an amorphous thin film material in step (204) and selective heating of the LSPs by MWI exposure in step (205). The steps (201) through (205), with modifications appreciated by one of ordinary skill in the art, can be applied to several other thin film dielectric materials, including the specific example described in FIG. 2B.

Generally, in the first step (201), a suitable chemical precursor solution is synthesized by the chemical solution deposition method, for example using a MOSD technique, to create the desired stoichiometric composition of the NLCO material. After the desired precursor solution is synthesized the LSP are added as previously indicated in step (202). The LSP may be obtained either by deposition or precipitation. Next, the precursor solution is disposed onto a substrate material as indicated in step (203). This can be accomplished by many methods, to include but not limited to, spin coating, spin casting, dip coating, extrusion etc. After disposing the precursor onto a substrate support, the substrate support with the disposed material is thermally heated to evaporate solvents in step (204), and an amorphous film is formed on the substrate support. Finally, the amorphous film-substrate entity is exposed to MWI processing in step (205), whereby the LSP are heated by the MW exposure allowing the creation of the poly-crystal domains within an amorphous matrix to form the nano-scale poly crystal-amorphous composite film artificial structure.

In a specific exemplary illustration, the process for the creation of a nano-scale poly crystal-amorphous composite film comprising a BaTiO₃ (BT) matrix surrounding inclusions in the form of BT crystalline particles is shown schematically in the method 206 shown in FIG. 2B and further depicted in FIGS. 3A through 3D. FIG. 2B describes a specialized example process 206 whereby crystalline BaTiO₃ (BT) in an amorphous matrix of the same chemical composition is created. Two processing routes are shown: One processing route comprises steps (207) through (215), inclusive. An optional processing route (216) can be undertaken after step (210), to include steps (213a), (214a), and (211a), and terminates with the final post-fabrication step (215).

With reference to FIGS. 2B through 3D, first, a metal-organic precursor solution 301, displayed in FIG. 3A, is provided in a vessel 300, and is prepared by a chemical solution technique such as a MOSD technique utilizing carboxylic salts and alkoxide chemical precursors. High-purity barium acetate is thoroughly dissolved in glacial acetic acid as indicated in step (207). Titanium isopropoxide is then added in step (208) to the solution 301, preferably in proportions to maintain 1:1 stoichiometry of barium and titanium. Additional solvents are added in step (209). Generally, an alcohol may be added to control the precursor viscosity, precursor molarity, or to promote the formation of BT amorphous particles/LSP particles 304, within the precursor solution 301 containing LSPs 303 such as illustrated in the vessel 302 of FIG. 3B. The solution 301 is maintained under constant stirring and sealed from the atmosphere as indicated in step (210) of FIG. 2B. The precursor solution 301 is then disposed onto a substrate support in step (211) of FIG. 2B. The solution 301 may be spin-coated onto a substrate 306 to form the thin film 307 (of FIG. 3C). Multiple coats of the same or additional solution may be used to build the thickness of the film 307. The thickness of the film 307 may range from 20 nm to 500 nm, more preferably from 100 nm to 300 nm, inclusive. Generally, the substrate 306 (of FIG. 3C) may be absorbing or non-absorbing depending on the desired result. In one example embodiment, a sapphire substrate is used without adding any absorber film, such as a metallic electrode. The excess solvent is removed by drying in step (212) in FIG. 2B. Generally, drying is obtained at elevated temperatures, for example, at 300° C. for 20 min., to create an amorphous film of BT 307 containing LSPs 304 overlying a substrate support 306 as depicted in the structure 305 shown in FIG. 3C. The BT film 307 is then exposed to microwave irradiation in step (213) of FIG. 2B and indicated by features 311 in FIG. 3D to promote the phase transition of the amorphous state to the crystalline state as given in step (214) of FIG. 2B. A post-fabrication process can occur as shown in step (215) of FIG. 2B to include device patterning, etching, encapsulation, etc.

Generally, the microwave parameters are controlled so that the growth of the crystalline particles does not proceed to a fully crystalline microstructure. The MWI process parameters may include: 2.45 GHz, at a microwave power of 100 W for 10 minutes, inclusive, and utilized to create the crystalline BT domains 310 which encapsulates the LSP 304 and are separated by the remaining amorphous BT matrix 309 as depicted in structure 308 of FIG. 3D. The solidification front 312 from the LSP 304 is also shown in FIG. 3D. Specifically, FIG. 3D illustrates a representation of the final nano-scale poly crystal-amorphous composite film 308 comprising a BaTiO₃ (BT) matrix 309 surrounding inclusions in the form of BT crystalline domains/particles 310 produced by the embodiments herein.

Step (216) in FIG. 2B illustrates an alternate fabrication route whereby the precursor solution generated in step (210) is exposed to limited MWI in step (213a) to permit regulated/controlled susceptor absorption of the precursor solution, whereby crystalline BT particles 310 suspended within the remaining BT solution are created in step (214a). The solution is disposed onto a substrate support 306 in step (211a) to form the poly crystal-amorphous composite film artificial structure 308.

FIGS. 4A and 4B, with reference to FIGS. 1 through 3D, illustrate TEM images 400, 402. More particularly, FIG. 4A is a reproduction of a TEM image 400 of the as-prepared precursor showing a BT particle 401 in the amorphous phase state. FIG. 4B is a reproduction of a TEM image 402 of the microwave irradiated precursors showing a BT particle 403 in the crystalline phase state.

The method provided by the embodiments herein can be utilized to enable several material designs offering performance and processing advantages with respect to the conventional techniques. Generally, the material selection and chosen combinations between LSP, matrix, and resulting crystalline domains can be used to modulate the resulting artificial structures, their properties, and possible applications. Specific structures and applications inclusive, but not limited to, are discussed below.

Specifically, the formation of a multiferroic (a combination of one or more ferroic phases) material can be created. A ferromagnetic (FM) susceptor phase could be chosen and placed in a ferroelectric (FE) matrix (preferably BST). This allows the possibility of forming artificial thin film material structures comprising small core-shell or thin-film heterostructures of FM/FE that are separated by the remaining amorphous (no polarization and no FM or FE behavior) boundaries.

Additionally, the formation of pyroelectric or ferroelectric arrays embedded in an amorphous matrix can be created. This type of device could be used for various purposes, including low-loss tunable varactors and enhanced pyroelectric sensors, and the present microwave LSP process could be used as an alternative method of fabrication for the devices. For example, crystalline barium titanate (BT) (finite pyroelectric/ferroelectric behavior) surrounded by amorphous barium titanate (non-pyroelectric). The microwave process provides a method to engineer and tailor the domain structures of these ferroelectric materials. Processing this material using MWI heating as described above.

Furthermore, the LSP and matrix may be chosen to have different thermal expansion coefficients. This could allow engineering the strain of the resulting poly-crystal domains as they cool from the microwave heating. This advent in strain engineering for thin film electroceramics, including NLCOs, would enable a close control of the state and extent of strain that results in unique properties, which are not observed in compositionally identical materials created by conventional materials processing techniques.

Moreover, the dispersed LSP and resulting crystalline domains could be chosen to have similar crystal structures and crystal lattice parameters. This allows the possibility of forming artificial thin film material structures comprising single crystal domain regions around dispersed LSPs. More ordered crystal structures would promote enhanced dielectric response for tunable NLCO based materials.

Further still, the dispersed LSP and resulting crystalline domains could be chosen to have different electronic properties. For example, the LSP and domains may comprise different conduction types (one n-type and one p-type) allowing the formation of localized pn-junctions. The amorphous matrix may be used as an insulator between the localized junctions.

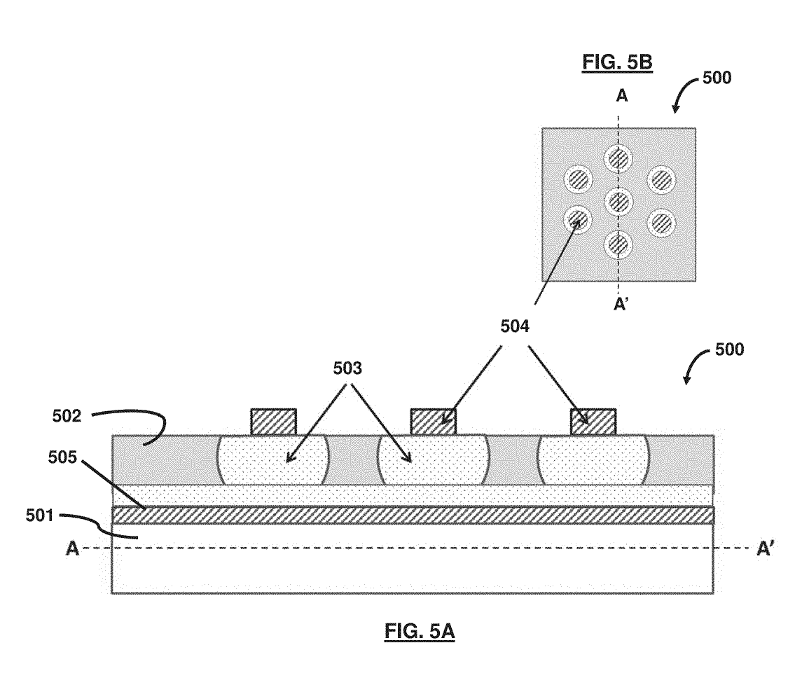

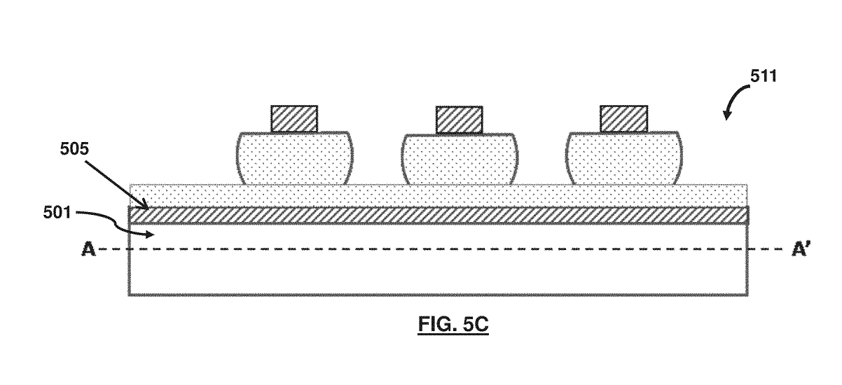

Also, the LSPs may be patterned onto the surface of a thin film, such as an array of dots, lines, etc., or the like. FIGS. 5A and 5B, with reference to FIGS. 1 through 4B, are schematic cross-sectional (FIG. 5A) and plan view (FIG. 5B) diagrams representing a metal-insulator-metal (MIM) capacitor array 500 fabricated by the embodiments herein. For example, localized heating of the LSP will then crystallize the portion of the film in contact with the patterned LSP to replicate the LSP pattern into crystalline domains in the film. Specifically, the capacitor array comprises a substrate support 501 that underlies the artificial thin film composite structure comprising an amorphous matrix 502 surrounding ordered arrays of crystalline domains 503 which are created by the MWI selective heating by the LSP electrodes. For example, the capacitor array comprises individual nano/micro capacitors, which are isolated from another by the remaining amorphous matrix phase.

FIG. 5A is a schematic cross-sectional 500 and plan view 510 diagram representing a metal-insulator-metal (MIM) capacitor array fabricated by the embodiments herein. For example, localized heating of the LSP will then crystallize the portion of the film in contact with the patterned LSP to replicate the LSP pattern into crystalline domains in the film. The capacitor array 500 comprises a substrate support 501 that underlies the artificial thin film composite structure comprising an amorphous matrix/regions 502 surrounding ordered arrays of crystalline domains/regions 503 which are selectively heated by LSP electrodes. The top electrodes 504 also act as LSPs. The bottom electrode 505 is the signal ground, according to an embodiment herein.

Additionally, the LSPs could also be removed, such as through etching, after microwave exposure. This type of protocol could also be used as a type of lithography process, whereby the crystalline regions 503 formed by the LSP heating are made to be insoluble and the amorphous regions 502 remain soluble to a developer solvent.

FIG. 5C, with reference to FIGS. 1 through 5B, is a schematic cross-sectional diagram representing a MIM capacitor array 511 as fabricated in FIGS. 5A and 5B, whereby the amorphous phase 502 is removed by selective dissolution in a developer solvent. Specifically, the MIM capacitor 511 is subjected to a lithographic protocol whereby the crystalline regions 503 formed by the LSP heating are made to be insoluble and the amorphous regions 502 remain soluble to a developer solvent. The resulting structure 511 is an array of individual nano/micro capacitors without the amorphous matrix present, according to an embodiment herein.

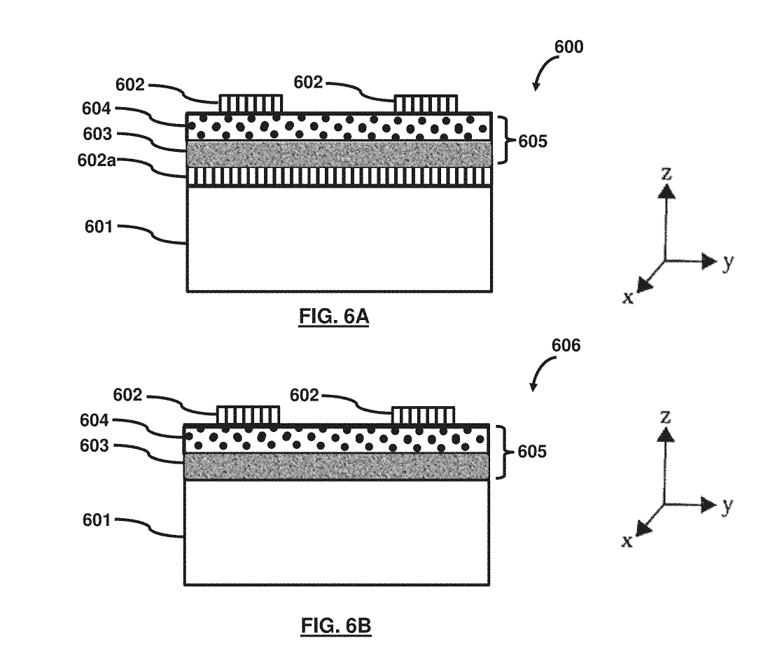

In addition to the nano-scale poly crystal-amorphous composite film variants described herein, other artificial thin film artificial structures can be created by the process provided by the embodiments herein. In particular, integrated layered NLCO thin film artificial structures are provided according to the embodiments herein whereby the microstructural crystallinity phase state is varied in the z-direction, perpendicular to the substrate support 501. Further descriptions of such NLCO thin film artificial structures are schematically presented in the exemplary embodiments illustrated in FIGS. 6A through 7B, and FIGS. 9A and 9B.

FIG. 6A, with reference to FIGS. 1 through 5C, displays a schematic cross-section of a device 600 comprising the basic building block/unit cell of the integrated layered NLCO thin film artificial structures, the bilayer, in the MIM device configuration. In the MIM device 600, the bilayer artificial structure 605 comprises an integrated NLCO structure having a lower layer n₁ 603 and an upper layer n₂ 604 of differing microstructural crystalline phase states whereby the bottom surface of the upper layer n₂ 604 is in contact with the top surface of the lower layer n₁ 603. Generally, the individual layers within the bilayer structure 605 are distinct from one another in microstructural crystalline phase state ranging from amorphous to quasi crystalline to fully crystalline. Depending on the property performance features desired the bilayer microstructural phase state layer configuration may be arranged such that the upper layer n₂ 604 is of a crystalline nature and the lower layer n₁ 603 ranges from an amorphous to crystalline phase state; or the bilayer may be formed in the reverse configuration. For example, considering the example feature of reducing leakage current in tunable devices, preferably, the bilayer phase state configuration comprises a fully crystalline upper layer n₂ 604 and amorphous lower layer n₁ 603. For example, considering the example feature of low dielectric loss, this or the reverse bilayer configuration is viable. The integrated artificial bilayer film structure 605 is in contact with a bottom electrode 602a overlying a substrate support 601 and has top electrodes 602 in electrical communication with the top surface of the bilayer structure 605.

FIG. 6B, with reference to FIGS. 1 through 6A, displays a schematic cross-section of a coplanar device 606 inclusive of the NLCO integrated bilayer artificial structure 605. In this configuration, the bilayer artificial structure 605 is an integrated NLCO structure comprising a lower layer n₁ 603 and an upper layer n₂ 604 of differing crystalline phase states whereby the bottom surface of the upper layer 604 is in contact with the top surface of the lower layer 603. Specifically, the individual layers within the bilayer structure 605 are distinct from one another in microstructural phase state ranging from amorphous to quasi crystalline to fully crystalline. Depending on the property performance features desired, the bilayer microstructural phase state layer configuration may be arranged such that the upper layer n₂ 604 is of crystalline nature and the lower layer n₁ 603 ranges from amorphous to crystalline, or the bilayer may be formed in the reverse configuration. The integrated artificial bilayer structure 605 is in contact with the top surface of the substrate support 601 and has top electrodes 602 in electrical communication with the top surface of the bilayer structure 605.

The materials for electrodes 602, 602a may include, but are not limited to, conductive oxides and noble metals with or without adhesion layers. For example, in the MIM device 600 the bottom electrode 602a and top electrodes 602 are compositionally symmetric. Preferably, the support substrate 601 is a large area device relevant low cost wafer, such as, but not limited to, sapphire, high resistivity Si, GaAs etc. The support substrate 601 may be MWI absorbing or MWI transparent, depending on the property performance features desired. The embodiments herein expand upon the “building block” unit cell bilayer artificial thin film material structure to create repeat bilayers with variable stacking periodicity (N) and multilayer artificial thin film material structures.

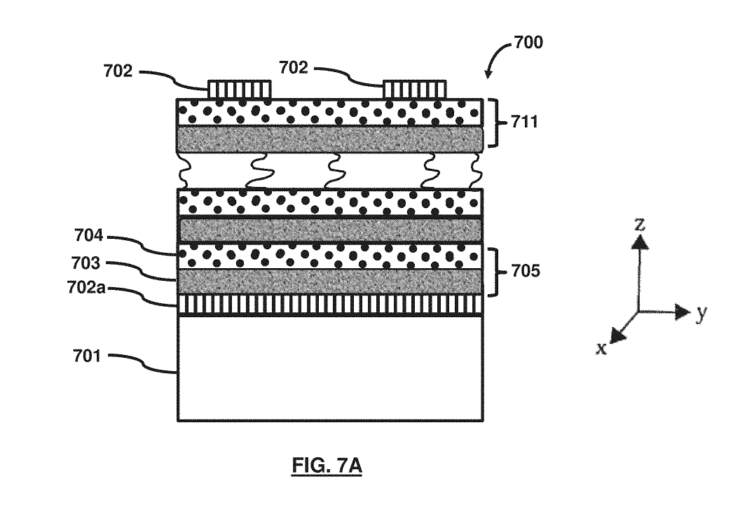

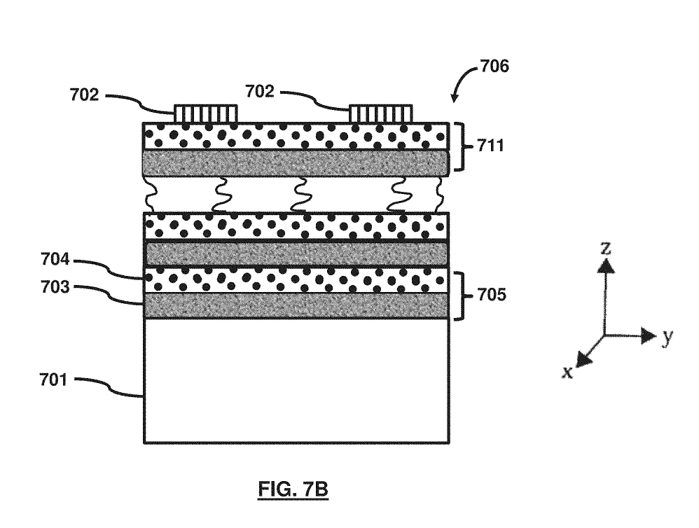

FIG. 7A, with reference to FIGS. 1 through 6B, displays a schematic cross-section of the MIM device 700 inclusive of the repeat “unit cell” bilayer 705 with variable stacking periodicity (N) comprising discrete variants n₁ 703 and n₂ 704 of differing microstructural crystalline phase states ranging from amorphous to quasi crystalline to fully crystalline in the of the MIM device configuration. The bottom surface of the upper layer n₂ 704 is in contact with the top surface of the lower layer n₁ 703. In the MIM device 700, the lowest section of integrated repeat artificial bilayer structure 705 is in contact with a bottom electrode 702a overlying a substrate support 701 and top electrodes 702 are in electrical communication with the top surface of the upper most bilayer structure 711.

The materials for the electrodes 702, 702a include, but are not limited to, conductive oxides and noble metals with or without adhesion layers. For example, in the MIM device 700 the bottom electrode 702a and top electrodes 702 are compositionally symmetric. Preferably, the support substrate 701 is a large area device relevant low cost wafer, such as, but not limited to, sapphire, high resistivity Si, GaAs, etc. The support substrate 701 may be MWI absorbing or MWI transparent, depending on the property performance features desired.

FIG. 7B, with reference to FIGS. 1 through 7A, displays a schematic cross-section of a coplanar device 706 inclusive of the integrated NLCO repeat bilayers with variable stacking periodicity (N) artificial structure 705. The discrete variants n₁ 703 and n₂ 704 comprise differing crystalline phase states ranging from amorphous to quasi crystalline to fully crystalline in the MIM device configuration. The bottom surface of the upper layer n₂ 704 is in contact with the top surface of the lower layer n₁ 703. In the coplanar device configuration, the lowest section of integrated repeat artificial bilayer structure 705 is in contact with a substrate support 701, and top electrodes 702 are in electrical communication with the top surface of the upper most bilayer structure 711.

Depending on the property performance features desired, the microstructural phase state of the layers within the unit cell bilayer 705 with variable stacking periodicity (N) may be arranged such that the upper layer n₂ 704 is of crystalline nature and the lower layer n₁ 703 ranges from amorphous to crystalline, or the bilayer may be formed in the reverse configuration. Specifically, considering the MIM device configuration and the example feature of reducing leakage current in tunable devices, the unit cell bilayer phase state configuration preferably comprises a fully crystalline upper layer n₂ 704 and amorphous lower layer n₁ 703, with a repeat periodicity N. For example, considering the example feature of low dielectric loss, this or the reverse bilayer configuration is viable in either the MIM device 700 or the coplanar device 706. Generally, depending on the property performance features desired the unit cell bilayer microstructural phase state layer configuration may be arranged such that the upper layer n₂ 704 is of crystalline nature and the lower layer n₁ 703, ranges from amorphous to crystalline, or the bilayer 705 may be formed in the reverse configuration with a repeat periodicity N.

Low dielectric loss NLCO thin films are desirable for RF/MW tunable devices. Additionally, for NLCO based tunable devices it is desirable to have a suitable thin film dielectric material that provides wide dielectric tunability, whereby tunability relates to the changes of dielectric constant as a function of applied electric field. Thin film materials having the greatest variability in the magnitude of the dielectric constant with low applied field are desired. Ba₁₋ₓSrₓTiO₃, preferably Ba_{0.60}Sr_{0.40}TiO₃ (BST60/40), possesses high values of dielectric tunability, optimally over 50-75%.

Generally, the individual layers, n₁ and n₂ 703, 704 of the bilayer 705 and the repeat bilayers with variable stacking periodicity (N) artificial structures may be of the same or differing chemical composition. For example, in the MIM device 700, to ensure low leakage currents, the lower layer, n₁ 703, of the bilayer artificial material structure 705 comprises a low loss linear or NLCO material such as, but not limited to, SrTiO₃ (ST) or other low loss linear dielectric material such as Al₂O₃, Ta₂O₅ or bismuth-zinc-niobate (BZN) pyrochlore films. The upper layer, n₂ 704, may comprise a highly tunable NLCO such as, but not limited to Ba₁₋ₓSrₓTiO₃ (BST), preferably Ba_{0.60}Sr_{0.40}TiO₃ (BST60/40). In the coplanar device configuration, this or the reverse configuration is desirable. Moreover, low loss dielectric materials, such as SrTiO₃, Al₂O₃, Ta₂O₅, BZN, etc. are materials, in which microwaves are transmitted through the material with minimal attenuation, hence such materials would not incur MW heating and will retain their as-deposited amorphous phase state microstructural characteristics after exposure to MWI processing.

Generally, the embodiments herein combine a low loss thin film dielectric layer in series with a highly tunable BST thin film layer, which serves to lower the effective dielectric loss of the composite structure while maintaining wide tunability. Moreover, a low loss amorphous film is placed in direct contact with the bottom electrode 702a, which serves to lower the leakage current of the device 700, 706.

The NLCO-based tunable devices possess low dielectric loss to maximize signal transmission and intensity, possess wide tunability to sustain agility and to possess low leakage currents to minimize power draw and maximize transmission range. Accordingly, the embodiments herein provide non-complex processing methods that are affordable and scalable to enable these desirable material properties to be achieved simultaneously within a single material design structure.

The bilayer and the repeat bilayers with variable stacking periodicity (N) artificial structures are achieved by utilizing a chemical solution deposition (CSD) film fabrication technique, such as a MOSD technique, in combination with a process parameter optimized MWI film heating technique, inclusive. The MOSD film deposition technique is attractive because it provides precise control of stoichiometry, high deposition rates, large area pinhole-free films, with excellent thickness uniformity across the wafer. The MWI technique is desirable as the material composition of an artificial material structure can be tailored to absorb, reflect or transmit the MW energy. Materials which absorb microwave energy transduce this energy into heat, hence result in a crystalline phase state. Materials which transmit or reflect MW energy will remain in the as-deposited amorphous phase state.

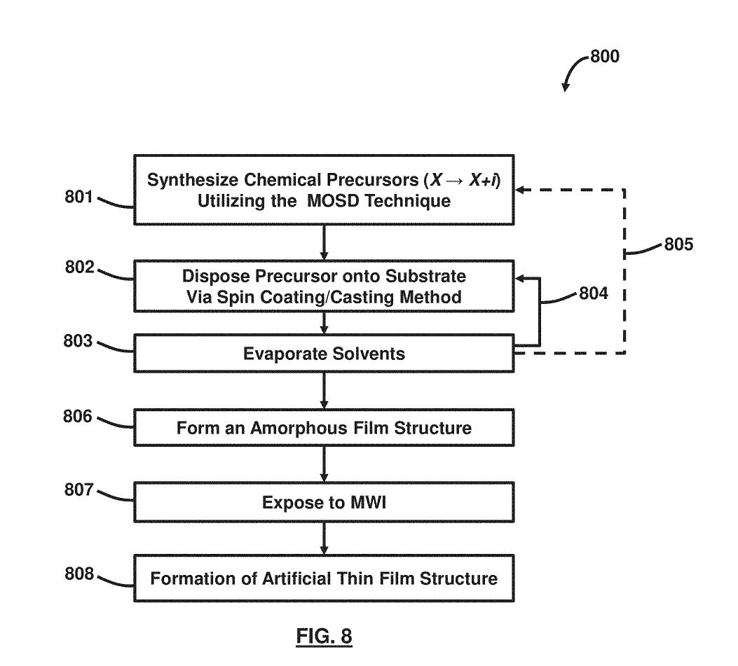

Generally, FIG. 8, with reference to FIGS. 1 through 7B, schematically illustrates a manufacturing process 800 according to an embodiment herein. More specifically, the manufacturing process 800 illustrates utilizing the carboxylic salts and an alkoxide precursor route of forming the bilayer, repeat bilayers with variable stacking periodicity (N) artificial structures and multilayer artificial structures. The processing steps include MOSD synthesis of chemical precursors in step (801), deposing precursors onto a substrate via spin coating in step (802), followed by pyrolization or evaporation of solvents in step (803). The spin coat pyrolization process is repeated in step (804) until the desired nominal film thickness is achieved and an amorphous thin film structure is created in step (806).

Step (801) of the process illustrated in FIG. 800 comprises the MOSD technique using carboxylate-alkoxide precursors of solution composition “X.” In step (802), the stoichiometric precursor solutions are concentration optimized and disposed, preferably by spin coating, onto device relevant substrates with or without a bottom electrode. Subsequent to coating, the films are pyrolyzed in step (803) at the optimized temperature-time parameter space to evaporate solvents and to attain the desired content of organic addenda; i.e. carbon concentration, required for tailoring the MW absorption characteristics of the thin film material. Spin coating-pyrolysis steps are repeated in step (804) to attain the layer film thickness desired and the amorphous film structure is achieved in step (806).

An alternate route (805) is utilized to attain individual layers of distinctly different chemical compositions. The amorphous film/substrate entity is exposed to MWI processing in step (807) to achieve the desired artificial thin film structure in step (808), namely, bilayers, repeat “unit cell” bilayers with variable stacking periodicity (N) and multilayers whereby each individual layer, nᵢ, exhibits a different microstructural crystallinity phase state.

Carbon is an excellent MW absorber. Thus, NLCO films with high concentrations of carbon content would serve to promote MW heating and those with minimal carbon concentrations would be non/less MW absorbing. Furthermore, as mentioned, low loss dielectric materials, such as SrTiO₃, Al₂O₃, Ta₂O₅, BZN, etc. are materials, in which microwaves are transmitted through the material with little attenuation, hence such materials would not incur MW heating.

Generally, ceramic NLCO materials with loss factors between the limits of 10⁻²<ε″<5 are good candidates for microwave heating. Optimally, Ba_{0.60}Sr_{0.40}TiO₃ (BST60/40) can be synthesized by the MOSD technique utilizing carboxylate-alkoxide precursors, whereby the organic addenda or carbon content within the film can be tailored during pyrolysis to achieve 10⁻²<ε″<5, hence can be tuned to absorb microwave energy.

For example, thin film BST60/40, which suitably, is one of the variants of the artificial structures, is pyrolyzed in step (803) at temperatures between approximately 250-350° C. for short temporal durations of 2-5 min. to retain the optimal carbon content to enable the NLCO film to be MW absorbing to permit heating of the layer by the MWI process, hence aid crystallization during MWI exposure in step (807). Alternatively, films may be pyrolyzed at higher temperatures ranging from approximately 350-500° C. for an extended temporal duration ranging from 10 to 30⁺ min. to minimize the carbon content to attain a low MW absorption state, and minimize susceptibility of the film MW heating, hence limit film crystallization during MW exposure.

As indicated, the spin coat pyrolization process is repeated in step (804) until the desired nominal film thickness is achieved and an amorphous thin film structure is created in step (806). For example, the thin film layer thickness is between 100 and 300 nm for a single bilayer artificial structure and between 10 and 100 nm for the repeat unit cell bilayers with variable stacking periodicity (N) artificial structures.

For example, to attain individual layers of distinctly different chemical compositions after the deposition of the first layer of composition “X”, the alternate route (805) is utilized. In this case a new precursor composition “Y” is synthesized in step (801) and steps (802) and (803) are repeated. An integrated bilayer thin film structure and/or the repeat “unit cell” bilayers with variable stacking periodicity (N) artificial structure comprising layers n₁ 703 and n₂ 704 with distinct chemical phase compositions from one another is formed in the microstructural amorphous phase state in step (806).

Generally, the amorphous layered film structures are exposed to process-parameter optimized MWI to create the tailored microstructural crystalline phase state of the bilayer and repeat unit cell bilayers with variable stacking periodicity (N) artificial structures, represented schematically in FIGS. 6A through 7B, respectively.

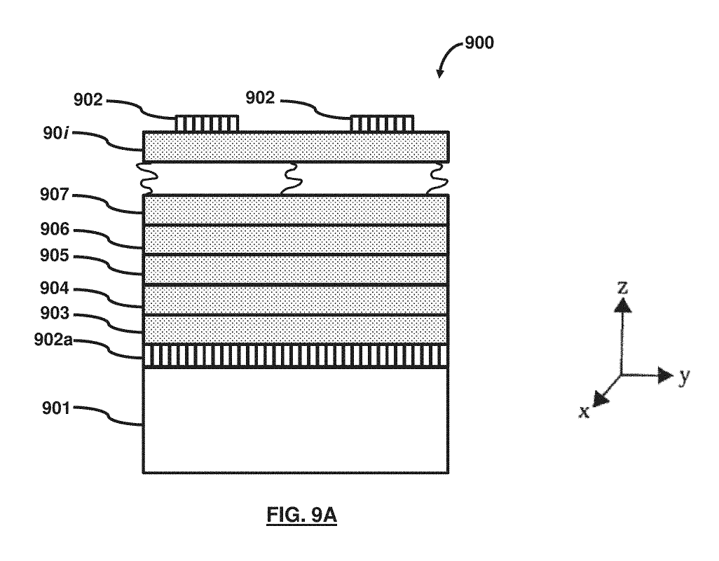

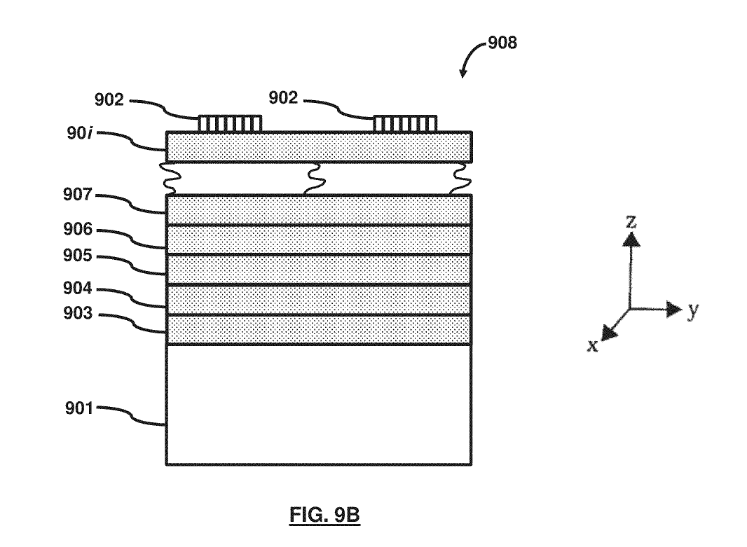

Beyond the bilayer and the repeat unit cell bilayers with variable stacking periodicity (N) artificial structures described herein, other artificial material configurations are enabled via the process provided by the embodiments herein. Such configurations include, but are not limited to, multilayer artificial thin film material structures whereby each individual layer variant, nᵢ, exhibits a different microstructural phase crystallinity, such that the microstructural phase state is variable in the vertical direction perpendicular to the substrate support as shown in FIGS. 9A and 9B, with reference to FIGS. 1 through 8. Such a tailored microstructural phase crystallinity architecture can be tuned to achieve a variety of material property responses not currently achievable by other conventional thin film materials processing methods. The individual variants nᵢ, within the artificial material design can be created to achieve a crystallinity up-grade (degree of crystallinity would range from amorphous n₁ to fully crystalline nᵢ) or down grade (the reverse). For example, the thin film layer thickness may be between 10 and 100 nm. The MOSD film synthesis can be adjusted to synthesize compositional distinct layers offering different levels of MWI absorption ranging from no absorption to maximum absorption to create the microstructural graded phase states. Specifically, each layer, with its distinct crystalline phase state, would possess a differing T_{c} with respect to the other layers in a graded fashion. For example, such a condition would cause the maximum in the dielectric permittivity to be broadened over a wide range of temperature. Such a configuration would be useful to promote improved material temperature stability. Material temperature stability is critical for device materials which are in systems that are exposed to a large range of diurnal and seasonal temperature fluctuations. Exposure to variable ambient temperatures causes undesirable changes in the device capacitance and disrupts the NLCO tunable device performance. Such disruption for communication systems applications manifests into device-to-device phase shift and/or insertion loss variations, leading to beam pointing errors and ultimately communication disruption and/or failure in the ability to receive and transmit the information. Thus, to ensure device performance consistency and reliability temperature stable devices are essential for fielded communications, radar, and EW systems.

In an specific example herein a MOSD fabricated amorphous BST60/40 film overlying a non-absorbing material/substrate can be compositionally tuned (maximizing the carbon content) to promote MW absorption, and optimally the amorphous film is pyrolyzed as indicated in step (803) of FIG. 8, at a temperature of approximately 300° C. for 3 min. prior to MWI exposure in step (807).

For example, the MWI process, (step (807) in FIG. 8) can be executed at a constant frequency of 2.45 GHz, at a power level of 900 W with a process time of 30 min., in an air ambience, inclusive. For example, the power may be ramped to 900 W at the rate of 180 W/min attaining a temperature and pressure of 63° C. and 11 bar, respectively; followed by a process hold time of 30 min. After the 30 min MWI processing interval, the temperature may be cooled to approximately 55° C., 11 bar over a 5-minute time interval. The MWI process parameters are represented in Table 1.

TABLE 1
MWI Process Parameters: sequence of ‘snap-shots’
in time of the ‘optimal’ MWI process

MWI
Parameters

| | | | | | | |
|---|---|---|---|---|---|---|
| Frequency | 2.45 | 2.45 | 2.45 | 2.45 | 2.45 | 2.45 |
| (GHz) | | | | | | |
| Power (Watts) | 900 | 900 | 900 | 900 | 900 | 900 |
| Ambiance | Air | Air | Air | Air | Air | Air |
| Time (Min) | 5 | 10 | 15 | 20 | 25 | 30 |
| Pressure (Bar) | 13.9 | 16.1 | 18.6 | 20.8 | 22.4 | 25 |
| Temperature | 87 | 97 | 101 | 108 | 110 | 113 |
| (° C.) | | | | | | |

FIG. 9A, with reference to FIGS. 1 through 8, displays a schematic cross-section of a multilayer artificial thin film material MIM device 900 whereby each individual layer variant, ni, 903, 904, 905, 906, 907, 90i exhibits a different microstructural crystallinity phase state, such that the microstructural phase state is variable in the vertical direction (z) perpendicular to the substrate support 901. The lower portion of the integrated artificial multilayer structure 900 is in contact with a bottom electrode 902a overlying a substrate support 901 and has top electrodes 902 in electrical communication with the top surface of the integrated multilayer thin film structure 90i.

FIG. 9B, with reference to FIGS. 1 through 9A, displays a schematic cross-section of the multilayer artificial thin film material coplanar device 908 whereby each individual layer variant, ni, 903, 904, 905, 906, 907, 90i exhibits a different microstructural crystallinity phase state, such that the microstructural phase state is variable in the vertical direction perpendicular (z) to the substrate support 901. The lower portion of the integrated artificial multilayer structure is in contact with the substrate support 901 and has top electrodes 902 in electrical communication with the top surface of the integrated multilayer thin film structure 90i.

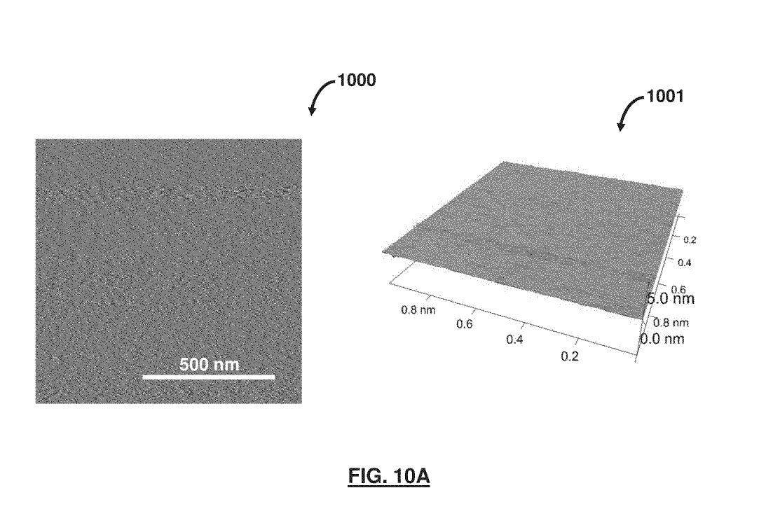

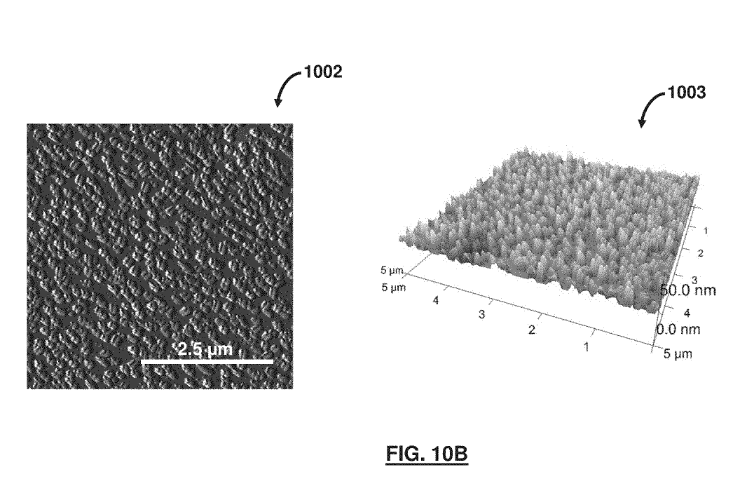

FIGS. 10A and 10B, with reference to FIGS. 1 through 9B, displays a plan view and 3D AFM images of the representative MOSD as deposited amorphous BST film 1000, 1001 and the crystallized BST60/40 film 1002, 1003 created by exposure to process parameter optimized MWI as described above. FIG. 10A displays the plan view and 3D AFM images 1000, 1001 of the representative MOSD as-deposited amorphous BST60/40 film. FIG. 10B displays the plan view and 3D AFM images 1002, 1003 of the representative MOSD as-deposited amorphous BST60/40 film after exposure to process parameter optimized MWI processing. The AFM results confirm that the BST film is effectively crystallized via MWI processing.

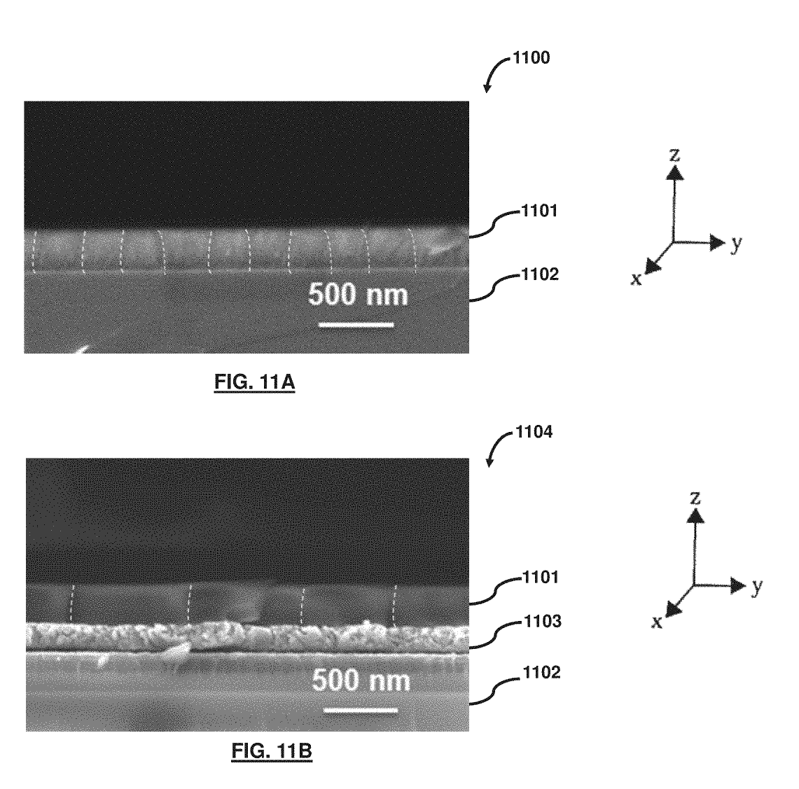

FIG. 11A, with reference to FIGS. 1 through 10B, displays the cross-sectional high resolution SEM image 1100 showing the crystalline nature of the BST60/40 film 1101 overlying a non-absorbing substrate 1102 after MWI processing. The resulting BST microstructure comprises a series of large highly oriented, well-ordered grains. The dotted lines serve to highlight the BST film's grain structure. Thus, MW heating is accomplished according to the embodiments herein in that the BST film is coupled with the EM energy of the MW field, hence forming a fully crystalline thin film layer. The MWI processed BST film forms a crystalline microstructure that is substantially distinct from that of conventionally fabricated BST films via MOSD-CFA. Generally, MOSD derived BST films crystallized via CFA/RTA thermal modes presents a polycrystalline microstructure, comprising small (of the order ˜20 nm) granular multi-grains randomly distributed throughout the film thickness. The BST film microstructure created by the process provided by the embodiments herein (MOSD+MWI) comprises a plurality of interconnected grains with a mean grain size of 235 nm whose grain length in the z-direction extends continuously from the top of the underlying material 1102 through-out the thickness of the film wherein the mean grain size is at least 89% of the film's thickness.

In a further option of the process provided by the embodiments herein, a MOSD fabricated amorphous BST60/40 film, compositionally tuned (maximizing the carbon content during the pyrolysis step) to promote MW absorption, is disposed on a bottom electrode material comprising Pt/TiO₂ 1103, preferably the Pt is 150 nm and the TiO₂ is 40 nm in thickness, overlying a microwave transparent substrate support 1102 as shown in FIG. 11B.

FIG. 11B, with reference to FIGS. 1 through 11A, displays a cross-sectional high resolution SEM 1104 showing the crystalline nature of the BST60/40 film 1101 after MWI processing. In this case a bottom electrode material comprising Pt/TiO₂ 1103 is sandwiched between the BST film 1101 and the non-MW absorbing substrate 1102. The bottom electrode 1103 acts as a LSP. The MWI process promotes self-heating of the BST film while at the same time the BST is conductively heated by the underlying bottom electrode, LSP material, to produce a near-single crystal microstructure in the BST film. The dotted lines serve to highlight the BST film's grain structure.

In this option the Pt/TiO₂ layer 1103 serves as a LSP material. During the MWI process the LSP material 1103 heats up and thermal energy is conductively transferred to the overlying BST film 1101. Therefore, the BST layer 1101 is heated both by the direct conversion of the MW energy into thermal energy (the compositionally tuned BST layer is well coupled to the EM field enabling self-heating of the BST film) and conductive heating provided by the LSP material it overlies. The resulting microstructure of the crystallized BST film is of a quasi-single crystal form, wherein the thin film BST60/40 has a thickness and a plurality of interconnected grains with a mean grain size of 785 nm, wherein the mean in-plane/lateral grain size is at least 2.9 times larger than the film's thickness.

Large grains provide higher dielectric tunability. Furthermore, a larger-grained microstructure means that there is less grain boundary area, and since grain boundaries can serve as high-leakage paths the leakage currents would be greatly reduced utilizing the process provided by the embodiments herein vs. conventional CFA/RTA methods to crystallize the film.

The process provided by the embodiments herein further reduces dielectric losses by promoting orderly crystal growth promoting a near-single crystal microstructure in the thin film dielectric material. The more ordered crystal structure has fewer grain boundaries with a more uniform distribution and there are relatively few defects, thereby reducing intra-granular scattering of the signal in RF/MW device applications. From the device point of view, decreases in dielectric losses are realized by the formation of relatively large grain sizes in the material, thereby substantially minimizing intra-granular scattering of the signal due to contact of the signal with a multiplicity of grain boundaries in the material.

The process provided by the embodiments herein substantially increases tunability and loss ratio compared to conventionally processed NLCO thin films. Moreover, the process provided by the embodiments herein, which combines MOSD film fabrication and MWI thermal processing, enables the creation of a variety of artificial thin film layered structures comprising tailorable microstructural phase state architectures in the vertical direction via a single thermal process step. Additionally, materials that are well coupled to the MW energy result in a desirably enhanced crystalline microstructure to enable materials property improvements for NLCO tunable devices. For example, the embodiments herein inclusive of associated process science methodology and materials, is foundry friendly, scalable and affordable.

NLCO thin film materials, such as Barium Strontium Titanate (BST), Barium Titanate (BT), Strontium Titanate (ST), and variations thereof, are desirable candidates to enable next generation wireless RF/microwave (MW) communications (electronically steerable antennas, hand held software defined/SWD radios), phased array radar and advanced electronic warfare/EW (jammer) systems. Specifically, it is the nonlinear dielectric property of these materials which makes them very useful for passive devices, such as tunable filters, phase shifters, varactors, and oscillators and matching networks, all of which are essential components to realize these advanced RF/MW systems.

A method that achieves microstructural agility; i.e., variable microstructure (variable film crystallinity) within a single thermal treatment process science step would provide enhancement in the properties and enable the possibility to design the artificial thin film material structures with microstructural crystallinity phase state control to achieve properties entirely different from the property of any of the parent members present. It is desirable to have a method which would permit microstructural agility of material crystallinity within artificial thin film material structures. At the same time to ensure economy of scale and device system affordability such a material process science method must be compatible with industrial manufacturing, preferably semiconductor industry compatible and affordable.

It is desirable to have a process that allows microstructural crystallinity phase state control via a single heat-treatment process step. It is also desirable that the processing methodology possess a low thermal budget; i.e. decreased temperatures and processing times (permits integration with less refractory materials/electrodes/substrates), facilitates process simplicity (create novel artificial material via a single heat-treatment process step) and is industry standard (promotes materials manufacturability and affordability).

From the material innovation point of view, it is highly desirable to attain tailored microstructural crystallinity phase state artificial thin film material structures comprising NLCO based thin films to enable new functionalities and enhanced material properties for RF/MW tunable devices. Such artificial thin film material structures include, but are not limited to, thin film multilayers of variable microstructural phase states, or other engineered composite thin films, namely a single layer film layer comprising highly ordered crystalline particles, rods, platelets, or nano-pillars embedded in a matrix differing in either composition and/or phase state. From the process science and manufacturing point of view it is desirable that the microstructural phase states be attained simultaneously within a single thermal process science step. It is also desirable that such a process be non-complex, energy efficient, possess a low thermal budget and be controllable. The process provided by the embodiments herein offers the ability to create novel artificial thin film material structures with variable microstructural crystallinity phase states; i.e., thin film structures comprising variants ranging from amorphous to fully crystalline phase states within a single MWI heating process step. Specifically, the process provided by the embodiments herein provides an artificial material structure comprising NLCO thin films whereby the thin film materials composition is tuned to achieve microstructural control within a single film layer and/or across a multilayer thin film structure. The process provided by the embodiments herein provides this feature via a hybrid technique which combines process parameter-optimized MOSD film fabrication with MWI thermal processing. The method provided by the embodiments herein serves to desirably tune material properties, and create new and unique novel artificial NLCO thin film architectures which offer ease of integration, manufacturability and affordability.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A method for forming integrated non-linear complex oxide (NLCO) thin film artificial structures comprising tailored microstructural phase states within a plurality of thin film layers, said method comprising:
forming a nano-scale poly crystal-amorphous composite film arranged in an array configuration; and
forming said tailored microstructural phase states of individual elements within the composite film using a hybrid fabrication process comprising metal-organic solution deposition (MOSD) film fabrication and microwave irradiation (MWI) processing.

2. The method of claim 1, wherein said composite film comprises an amorphous matrix surrounding domains and inclusions in the form of any of crystalline particles, platelets, rods and needles.

3. The method of claim 2, wherein said plurality of thin film layers comprise bilayers, repeat unit cell bilayers with variable stacking periodicity, and multilayers, and wherein each individual layer exhibits a different microstructural crystallinity phase state.

4. The method of claim 1, wherein the artificial structures are configured in any of a metal-insulator-metal (MIM) and a coplanar device configuration comprising a substrate and conducting electrodes.

5. The method of claim 1, wherein a material composition of said composite film produced by said MOSD film fabrication is compositionally tailored such that said material composition absorbs, reflects or transmits microwave (MW) energy during said MWI processing to produce materials of varied microstructural crystallinity phase states, ranging from amorphous to quasi-crystalline to fully crystalline microstructural phase states.

6. The method of claim 3, wherein said MWI processing comprises MWI process parameters comprising MW frequency, MW power level, process time, pressure, temperature, ambience, and a presence of an external MW susceptor, and wherein said MWI process parameters are tuned and optimized to tailor heating of said composite film.

7. The method of claim 1, wherein said MOSD film fabrication comprises chemical syntheses of NLCO material compositions, phases, and states of matter to produce any of MW absorption, non-absorption, and partial absorption solutions.

8. The method of claim 7, wherein the solutions are disposed onto a substrate using a spin coating method and disposed material of said composite film is thermally heated to evaporate solvents to form an amorphous film on said substrate.

9. The method of claim 4, wherein said substrate is any of MW absorbing, MW non-absorbing, and MW reflecting.

10. The method of claim 4, wherein a bottom electrode of said conducting electrodes comprises a noble metal and behaves as a localized susceptor phase (LSP) to further modify a microstructure of material with which said bottom electrode is in contact.

11. The method of claim 8, wherein said MWI processing lowers a thermal strain in said disposed material.

12. The method of claim 6, wherein said composite film utilizes localized susceptor phases (LSPs), and wherein said LSPs are any of crystalline and amorphous phases dispersed or layered into said amorphous matrix.

13. The method of claim 12, wherein said composite film comprises a low loss microwave (MW) material that does not absorb MW energy generated by said MWI processing, and wherein matrix material not in direct contact with said LSPs retain an amorphous phase state as produced by said MOSD film fabrication.

14. The method of claim 12, wherein said LSPs behave as local-source susceptors to convert impinging microwave (MW) energy generated by said MWI processing into localized heating of a finite portion of a surrounding amorphous matrix of which they are in direct contact, thereby creating poly-crystal domains by conductive heating.

15. The method of claim 14, wherein said MWI processing promotes a phase transition of the amorphous phase to the crystalline phase thereby forming crystalline domains/particles whose center is a LSP material.

16. The method of claim 14, wherein a concentration of said LSPs directly controls the number of poly-crystals domains.

17. The method of claim 6, wherein said MWI process parameters are tuned to determine a size of said poly crystal domains.

18. The method of claim 1, wherein said artificial structures are composed of variants of the form of individual layers fabricated by said MOSD film fabrication and exposed to a single MWI heating step.

19. The method of claim 1, wherein said artificial structures are configured such that an arrangement of layers composed of differing microstructural phase state crystallinity reduces dielectric loss, improves leakage current characteristics, provides tenability, and increases temperature stability.

20. The method of claim 3, wherein each individual layer variant exhibits different microstructural phase crystallinity, such that said microstructural crystallinity phase state is arranged in any of a crystallinity up-grade and a crystallinity downgrade configuration.
